(19) United States
(12) Patent Application Publication
(10) Pub. No.: US 2023/0267526 A1
(43) Pub. Date: Aug. 24, 2023

(54) ANALYZING AND TRACKING USER ACTIONS OVER DIGITAL TWIN MODELS AND IN THE METAVERSE

(71) Applicant: Mattertraffic Inc., Shoreham, NY (US)

(72) Inventors: Diego Orofino, Spring Hill, FL (US); Marc Alessi, Shoreham, NY (US)

(21) Appl. No.: 18/102,987

(22) Filed: Jan. 30, 2023

Related U.S. Application Data
(60) Provisional application No. 63/311,651, filed on Feb. 18, 2022.

(51) Int. Cl. G06Q 30/0601; G06F 30/27; G06Q 30/0201

(52) U.S. Cl. CPC G06Q 30/0631; G06F 30/27; G06Q 30/0201

(57) ABSTRACT

A method includes receiving data corresponding to navigation by a user in at least one of a digital twin model and a metaverse, and analyzing the data to determine one or more user engagements with one or more objects in at least one of the digital twin model and the metaverse. In the method, one or more products corresponding to the one or more objects are identified, and one or more links to the one or more products on one or more electronic commerce websites are dynamically generated. The one or more links are provided to the user.

### FIELD

The field relates generally to information processing, and more particularly to techniques for the analysis and tracking of user activity in connection with digital twin models and the metaverse.

### BACKGROUND

Digital twins are three-dimensional (3D) virtual models designed to reflect physical objects and/or places such as, for example, apartments, houses, rooms, offices and the objects therein. A digital twin displayed on a user device may be used in, for example, industries like real estate, construction, entertainment and in other digital economy applications to present different spaces to customers, buyers or other users. A metaverse can comprise network of 3D virtual models and/or 3D virtual worlds. A virtual world (also referred to as a “virtual space”) is a computer-simulated environment, which may be populated by many users each associated with a personal avatar. Individual users may simultaneously and independently explore the virtual world, participate in its activities and communicate with others. Avatars may be, for example, in textual, graphical or video form. A metaverse may have digital economy implications by allowing users transport virtual objects (e.g., clothes, furniture, cars etc.) from one virtual model to another.

### SUMMARY

Illustrative embodiments correspond to techniques for analyzing user actions associated with navigation through a digital twin model(s) and/or inside the metaverse.

In one embodiment, method comprises receiving data corresponding to navigation by a user in at least one of a digital twin model and a metaverse, and analyzing the data to determine one or more user engagements with one or more objects in at least one of the digital twin model and the metaverse. In the method, one or more products corresponding to the one or more objects are identified, and one or more links to the one or more products on one or more electronic commerce websites are dynamically generated. The one or more links are provided to the user.

In an example embodiment, a system identifies user actions originating from a digital twin model(s) and/or the metaverse that lead to purchase conversion. In a non-limiting example, a user navigates to an object in the digital twin model or metaverse and the object is identified as a potential object of interest to the user. The user engages with a dynamically generated link, which leads the user to an electronic commerce (e-commerce) website where the user can purchase the object. The e-commerce website sends a signal back into the system, flagging the user purchase as a purchase conversion.

Further illustrative embodiments are provided in the form of a non-transitory computer-readable storage medium having embodied therein executable program code that when executed by a processor causes the processor to perform the above steps. Still further illustrative embodiments comprise an apparatus with a processing platform configured to perform the above steps.

### BRIEF DESCRIPTION OF THE DRAWINGS

FIG. 1 is a block diagram of an information processing system configured for analyzing and tracking user activity through a digital twin model(s) and/or the metaverse in an illustrative embodiment.

FIG. 2 is an operational flow diagram for analyzing and tracking user activity through a digital twin model(s) and/or the metaverse in an illustrative embodiment.

FIG. 3 is an operational flow diagram for product identification in connection with the analysis and tracking of user activity through a digital twin model(s) and/or the metaverse in an illustrative embodiment.

FIG. 4 is an operational flow diagram for visual product identification in connection with the analysis and tracking of user activity through a digital twin model(s) and/or the metaverse in an illustrative embodiment.

FIG. 5 is an operational flow diagram for advertisement media generation in connection with the analysis and tracking of user activity through a digital twin model(s) and/or the metaverse in an illustrative embodiment.

FIG. 6 is an operational flow diagram illustrating storing of user and/or avatar analytic data in a blockchain in an illustrative embodiment.

FIG. 7 is a flow diagram of a method for analyzing and tracking user activity through a digital twin model(s) and/or the metaverse in an illustrative embodiment.

FIGS. 8 and 9 show examples of processing platforms that may be utilized to implement at least a portion of an information processing system in illustrative embodiments.

### DETAILED DESCRIPTION

Illustrative embodiments will be described herein with reference to exemplary processing systems and associated computers, servers, storage devices and other processing devices. It is to be appreciated, however, that embodiments are not restricted to use with the particular illustrative system and device configurations shown.

As used herein, “real-time” refers to output within strict time constraints. Real-time output can be understood to be instantaneous or on the order of milliseconds or microseconds. Real-time output can occur when the connections with a network are continuous and a user device receives messages without any significant time delay. Of course, it should be understood that depending on the particular temporal nature of the system in which an embodiment is implemented, other appropriate timescales that provide at least contemporaneous performance and output can be achieved.

As used herein, “natural language” is to be broadly construed to refer to any language that has evolved naturally in humans. Non-limiting examples of natural languages include, for example, English, Spanish, French and Hindi.

As used herein, “natural language processing (NLP)” is to be broadly construed to refer to interactions between computers and human (natural) languages, where computers are able to derive meaning from human or natural language input, and respond to requests and/or commands provided by a human using natural language.

As used herein, “natural language understanding (NLU)” is to be broadly construed to refer to a sub-category of natural language processing in artificial intelligence (AI) where natural language input is disassembled and parsed to determine appropriate syntactic and semantic schemes in order to comprehend and use languages. NLU may rely on computational models that draw from linguistics to understand how language works, and comprehend what is being said by a user.

As used herein, “image” is to be broadly construed to refer to a visual representation which is, for example, produced on an electronic display such as a computer screen or other screen of a device. An image as used herein may include, but is not limited to, a screen shot, window, message box, error message or other visual representation that may be produced on a device. Images can be in the form of one or more files in formats including, but not necessarily limited to, Joint Photographic Experts Group (JPEG), Portable Network Graphics (PNG), Graphics Interchange Format (GIF), and Tagged Image File (TIFF).

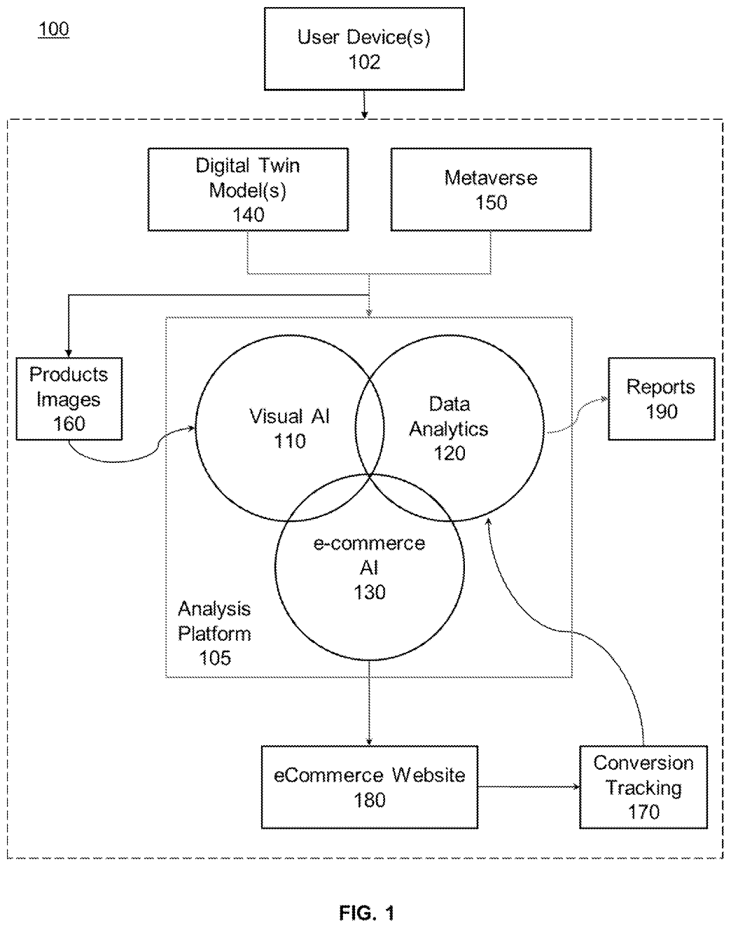

FIG. 1 shows an information processing system 100 configured in accordance with an illustrative embodiment. The information processing system 100 comprises one or more user devices 102, an analysis platform 105, one or more digital twin models 140 and a metaverse 150. The analysis platform 105 comprises a visual artificial intelligence (AI) module 110, a data analytics module 120 and an electronic commerce (e-commerce) AI module 130. As explained in more detail herein, the analysis platform 105 receives product images 160 as input to train one or more machine learning models used by the visual AI and/or e-commerce AI modules 110 and 130.

In accordance with an embodiment, the analysis platform 105 receives data corresponding to navigation by a user in a digital twin model(s) 140 and/or in a metaverse 150. As used herein, a digital twin model is to be broadly construed to refer to, for example, a 3D virtual model designed to reflect physical objects and/or places such as, for example, apartments, houses, rooms, offices and the objects therein. A digital twin model displayed on a user device may be used in, for example, industries like real estate, construction, entertainment and in other digital economy applications to present different spaces to customers, buyers or other users. As used herein, a metaverse is to be broadly construed to refer to, for example, a network of 3D virtual models and/or 3D virtual worlds. A virtual world (or virtual space) is a computer-simulated environment, which may be populated by many users each associated with a personal avatar. In the virtual world or virtual space users, via their avatars can play, or interact with other people or avatars.

Users can access the digital twin model(s) 140 and/or the metaverse 150 through user devices 102 over one or more networks. As used herein, a network can refer to, but is not necessarily limited to, a local area network (LAN), wide area network (WAN), cellular network, satellite network, the Internet or combinations thereof. Network communication can be performed via one or more centralized servers or cloud data centers that receive, analyze and send data to and from one or more user devices 102, such as, for example, smart phones, tablets, desktops, laptops, virtual reality glasses or other processing or computing devices, that, by way of example, are part of the network. Connections shown in the figures by lines and/or arrows may be network connections.

The data corresponding to the navigation by a user in a digital twin model(s) 140 and/or in a metaverse 150 comprises, for example, cookie data (or other files created by websites visited by the user), user click history, user mouse activity and time spent on one or more objects in the digital twin model(s) 140 and/or in a metaverse 150. Objects in the digital twin model(s) 140 and/or in a metaverse 150 comprise, for example, virtual renditions of objects appearing in the physical world, including, but not necessarily limited to, household and office items, furniture, food, beverages, appliances, clothing, tools, toys, vehicles, electronic items or any other items that may appear in the physical world. Such objects are also typically available to be bought and sold via one or more e-commerce websites 180. The e-commerce websites 180 may comprise known e-commerce websites 180 such as, but not necessarily limited to, store websites (e.g., Walmart, Target, Best Buy, etc.) and dedicated online websites such as, but not necessarily limited to, Amazon, Wayfair, eBay, etc.

The visual AI module 110 and/or the data analytics module 120 analyzes the navigation data to determine user engagements with the objects in the digital twin model(s) 140 and/or the metaverse 150. For example, a user may show interest in one or more objects in the digital twin model(s) 140 and/or the metaverse 150 by virtually touching the object via an interfacing device such as, but not necessarily limited to, a keyboard, mouse, stylus, virtual reality glove or wand, game controller, hand on a touchscreen or other interfacing device. For example, a user may click on an object with a mouse in an attempt to extract information about the object. One or more machine learning models may be used to analyze the navigation data.

The visual AI module 110 uses one or more machine learning models to identify one or more products corresponding to the one or more objects. For example, the one or more machine learning models interpret images in the digital twin model(s) 140 and/or the metaverse 150 representing the objects, and match them with products that may be available for sale on e-commerce websites 180. The machine learning models are trained to recognize objects as commercial products. The training data comprises, for example, product images 160 from, for example, online catalogs of products from e-commerce websites 180, or other sources connecting images with products available for sale.

According to an embodiment, the identification of the one or more products includes extracting text from one or more images (e.g., brand names, product identifiers, product labels, etc.) and performing NLP and NLU of the extracted text to identify the product that corresponds to an object. Although the embodiments herein are discussed in terms of images, the embodiments may alternatively apply to videos produced on a device in one or more formats such as, but not necessarily limited to, Moving Picture Experts Group (MPEG), Audio Video Interleave (AVI) and Windows Media Video (WMV).

The e-commerce AI module 130 uses one or more machine learning models to dynamically generate one or more links to the one or more products on one or more e-commerce web sites 180, and the links are provided to the user via a user device 102. The links may be provided on or adjacent the objects in the digital twin model(s) 140 and/or the metaverse 150. For example, based on the output of the visual AI module 110 identifying products corresponding to the one or more objects, the e-commerce AI module 130 determines the e-commerce websites 180 including the one or more products, and identifies prices associated with the products on respective ones of the e-commerce websites 180. According to an embodiment, the e-commerce AI module 130 ranks the respective ones of the e-commerce websites 180 according to the price associated with the products so that the e-commerce websites 180 with the cheapest prices for the products are presented to the user ahead of the e-commerce websites 180 with more expensive prices for the products.

A conversion tracking module 170 receives a signal from a given e-commerce website indicating that the user purchased the one or more products. The signal may be in the form of Java script, a cookie, image identifier (e.g., pixel) or other identifying information indicating that the user has purchased the product following navigation to the e-commerce website 180 by the provided link. The conversion tracking module 170 flags the purchase of a product as a purchase conversion and provides this information to the data analytics module 120, which generates one or more reports corresponding to the purchase conversions. For example, in the case of an enterprise that provides a platform for the analysis of the navigation activity by users in the digital twin model(s) 140 and/or in the metaverse 150, and for the generation of e-commerce website links to products based on the analysis, administrators or other professionals of the enterprise receive the reports 190. The reports can be used to track payments (e.g., commissions) owed to the enterprise for purchase conversions which are the result of the enterprise provided navigation analysis, product identification and link generation.

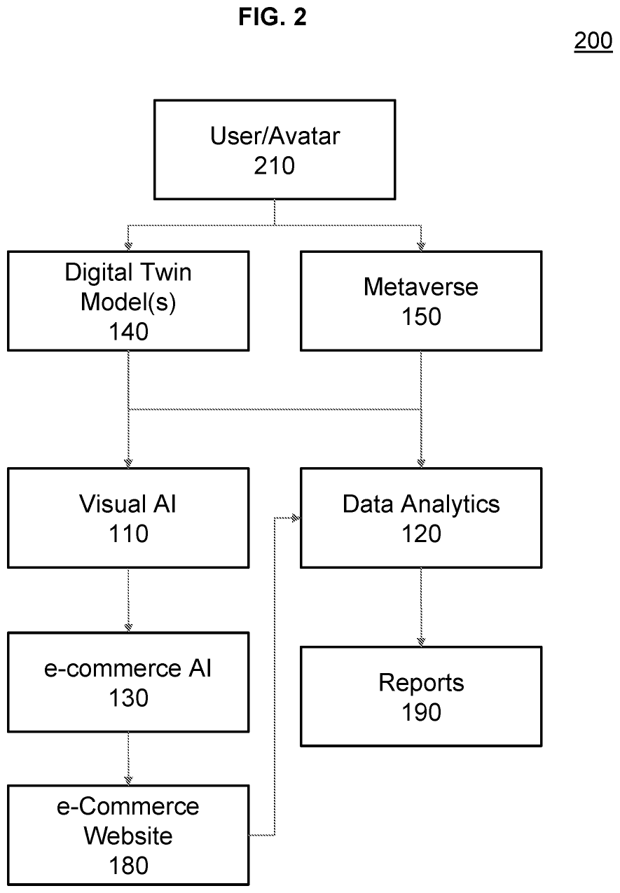

Referring to the operational flow 200 in FIG. 2, at block 210, a user accesses digital twin model(s) 140 and/or the metaverse 150 through a user device 102. As shown in block 210, the user may be controlling an avatar in the metaverse 150. As described herein above, the visual AI module 110 and/or the data analytics module 120 analyzes the user navigation data to determine the user engagements with the objects in the digital twin model(s) 140 and/or the metaverse 150. The visual AI module 110 uses one or more machine learning models to identify products corresponding to the objects and match them with products that may be available for sale on e-commerce websites 180. The e-commerce AI module 130 uses one or more machine learning models to dynamically generate one or more links to the one or more products on one or more e-commerce websites 180, and the links are provided to the user via a user device 102. Based on a signal or message from a given e-commerce website indicating that the user purchased the one or more products, the purchase of the product is flagged as a purchase conversion. The data indicating the purchase conversion is provided to the data analytics module 120, which generates reports 190 corresponding to purchase conversions.

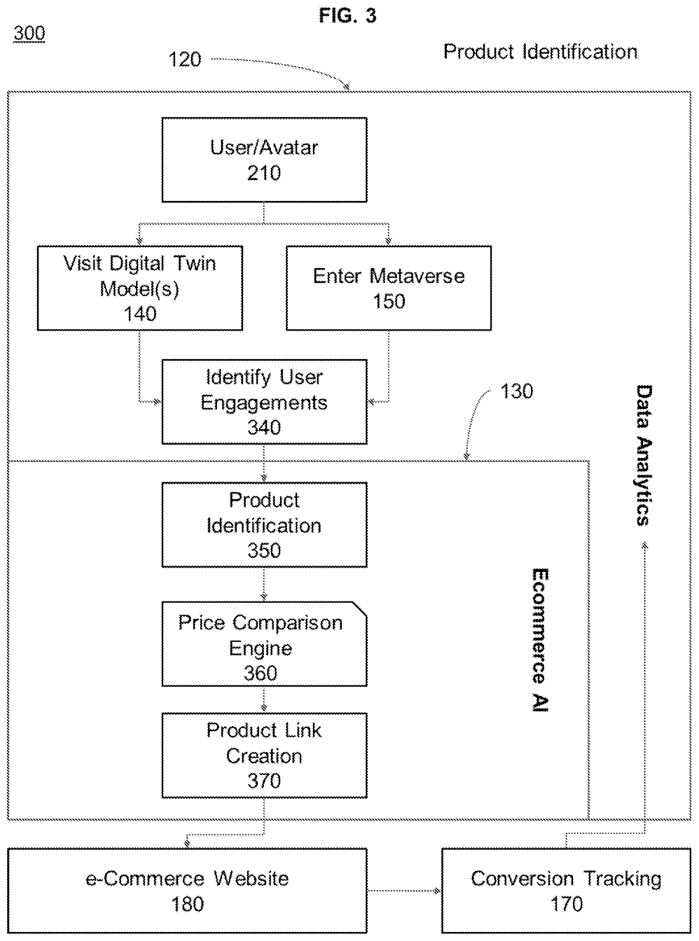

Referring to FIG. 3, the operational flow 300 details product identification in connection with the analysis and tracking of user activity through the digital twin model(s) 140 and/or the metaverse 150. A user visits digital twin model(s) 140 and/or enters the metaverse 150 through a user device 102. Referring to block 340, the user navigation data in the digital twin model(s) 140 and/or in the metaverse 150 is analyzed to determine user engagements with objects. The user navigation may comprise, but is not necessarily limited to, a user exhibiting interest in one or more objects in the digital twin model(s) 140 and/or the metaverse 150 by virtually touching the object via an interfacing device in an attempt to extract information about the object.

Referring to block 350, one or more machine learning models are used to identify one or more products corresponding to the objects with which the user engaged or is engaging in real-time. For example, the one or more machine learning models interpret metadata in the digital twin model(s) 140 and/or the metaverse 150 representing the objects, and matches the metadata with products that may be available for sale on e-commerce websites 180. The metadata may include, for example, identifying information for the objects such as, but not necessarily limited to, product names, model numbers and/or previously existing e-commerce web site links to the objects already present in the digital twin model(s) 140 and/or the metaverse 150. As noted herein, the identification of the one or more products can also include text extraction from one or more images (e.g., brand names, product identifiers, product labels, etc.) and performing NLP and NLU of the extracted text to identify the product that corresponds to an object.

A price comparison engine 360 identifies prices associated with identified products on respective e-commerce websites 180 and compares the prices to determine which of the e-commerce websites is offering the lowest price. According to an embodiment, the respective e-commerce websites 180 are ranked according to the price associated with a product so that links to the e-commerce websites 180 with the cheapest prices are presented to a user ahead of links to the e-commerce web sites 180 with more expensive prices for the product.

Referring to block 370, based at least in part on the analysis by the price comparison engine 360, one or more links to buy an identified product on one or more e-commerce websites 180 are created, and the link(s) are provided to the user via a user device 102. For example, the links may be provided on or adjacent the corresponding objects in the digital twin model(s) 140 and/or the metaverse 150.

As noted herein above, the conversion tracking module 170 receives a signal from a given e-commerce website indicating that the user purchased the one or more products after navigating to the provided link, and activates a flag indicating a purchase conversion for the one or more products, which is provided to the data analytics module 120 for generation of reports corresponding to purchase conversions so that enterprises can account for revenue from their analysis of user navigation activity and link generation.

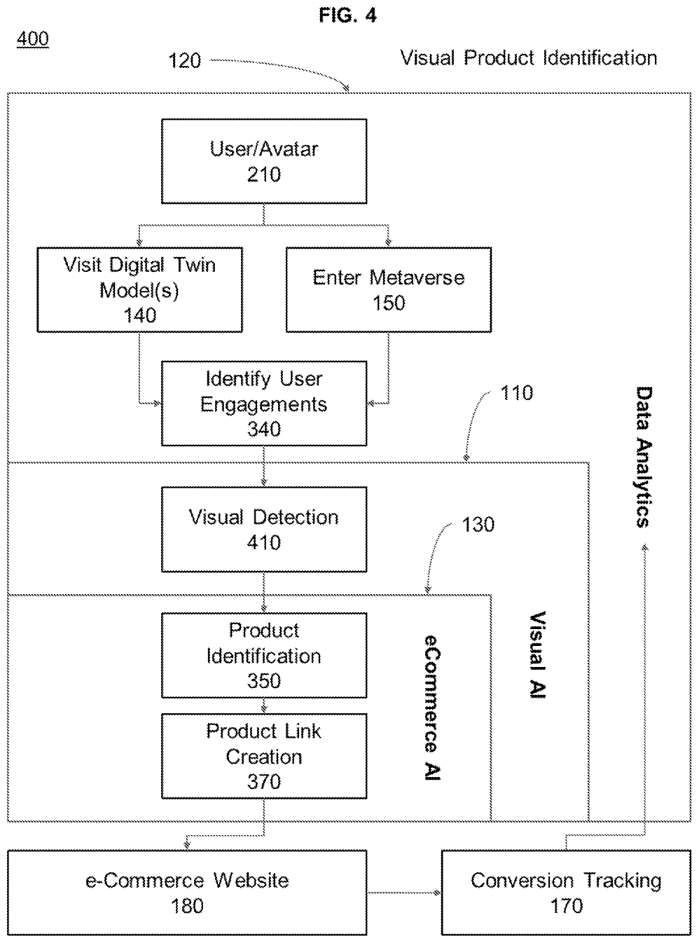

As can be seen, FIG. 3 provides an embodiment without a visual AI module 110, where product identification and subsequent link creation is performed based on analysis of non-image data such as, but not necessarily limited to, metadata and/or textual data. As can be seen, FIG. 4, which is similar to FIG. 3, further includes visual detection 410 of the object images in the digital twin model(s) 140 and/or metaverse 150 by the visual AI module 110. For example, the visual AI module 110 interprets images in the digital twin model(s) 140 and/or the metaverse 150 representing the objects, and matches them with products that may be available for sale on e-commerce websites 180. The machine learning models are trained to recognize objects as commercial products. As noted herein above, the training data comprises, for example, product images 160 from, for example, online catalogs of products from e-commerce websites 180, or other sources mapping images to products available for sale. Similar processing to that in FIG. 3 for product identification 350, product link creation 370 and purchase conversion tracking 170 are shown in FIG. 4.

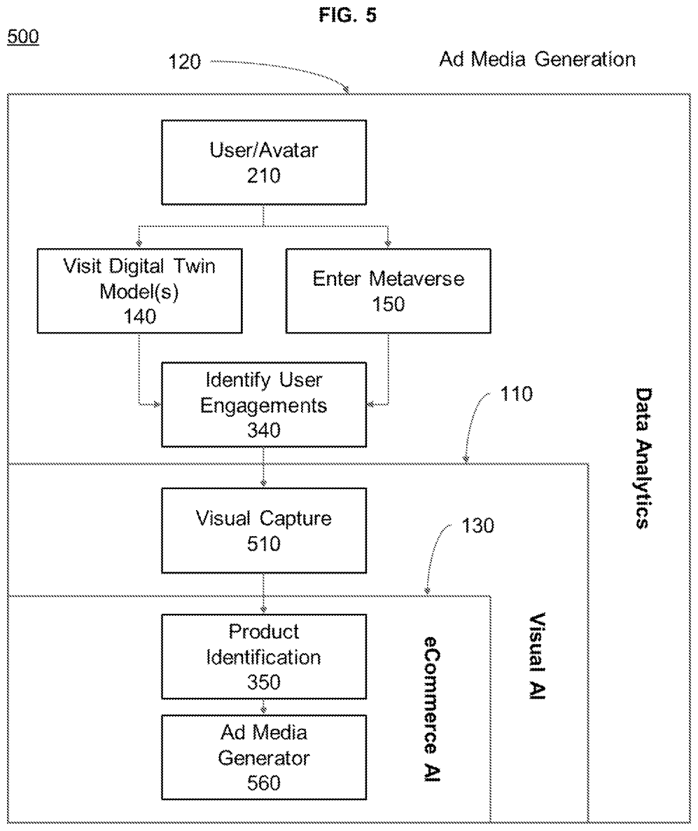

FIG. 5 depicts an operational flow 500 for advertisement media generation in connection with the analysis and tracking of user activity through a digital twin model(s) 140 and/or the metaverse 150. Following the identification of user engagements 340 for which processing up to this point is the same or similar to that in FIGS. 3 and 4, referring to block 510, the visual AI module 110 captures one or more images of one or more user engagements with the one or more objects. For example, a user may be navigating through a digital twin model(s) 140 and/or the metaverse 150, and engage with one or more objects as described herein. The visual AI module 110, for example, takes a snapshot of the user engagement(s) with the object(s) in the digital twin model(s) 140 and/or the metaverse 150. Like block 350 in FIGS. 3 and 4, one or more products corresponding to the objects with which the user engaged or is engaging in real-time are identified. Based on the identified products and the captured user engagement image of the object, an ad media generator 560 generates an advertisement comprising an image of the identified product and/or the captured user engagement image, which may be presented to the user when browsing on a website (e.g., as a pop-up advertisement) or while the user is visiting the digital twin model(s) and/or the metaverse 150. In some embodiments, the advertisement further includes a link to e-commerce website where the identified product may be found.

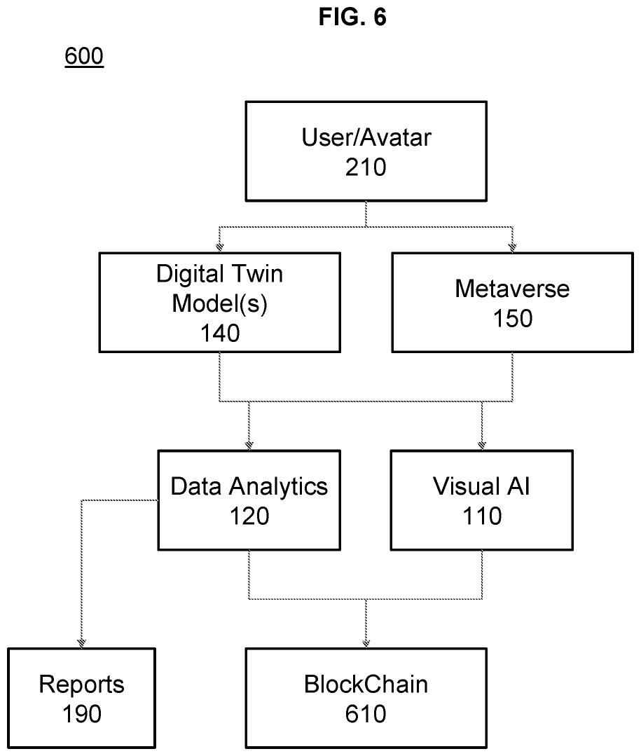

FIG. 6 depicts an operational flow 600 illustrating storing of user and/or avatar analytic data in a blockchain 610. Similar to FIG. 2, at block 210, a user accesses digital twin model(s) and/or the metaverse 150 through a user device 102. As shown in block 210, the user may be controlling an avatar in the metaverse 150. As described herein above, the visual AI module 110 and/or the data analytics module 120 analyzes the user navigation data to determine the user engagements with the objects in the digital twin model(s) 140 and/or the metaverse 150. According to an embodiment, the user navigation data and the results of the analysis of the user navigation data are provided to the blockchain 610 for storage of the user navigation data and analysis results. For example, the data may be stored for each user and comprise respective blockchain entries for respective users, the respective blockchain entries comprising each user's navigation history and corresponding analysis. Such data and corresponding block chain entries may be the property of each user. The reports 190 of the purchase conversions for respective users may also be components of the blockchain entries for each user. As used herein, a blockchain is to be broadly construed to refer to, for example, a continuously growing list of records (e.g., blocks) that are linked together using cryptography, with each block containing a cryptographic hash of the previous block, a timestamp, and data.

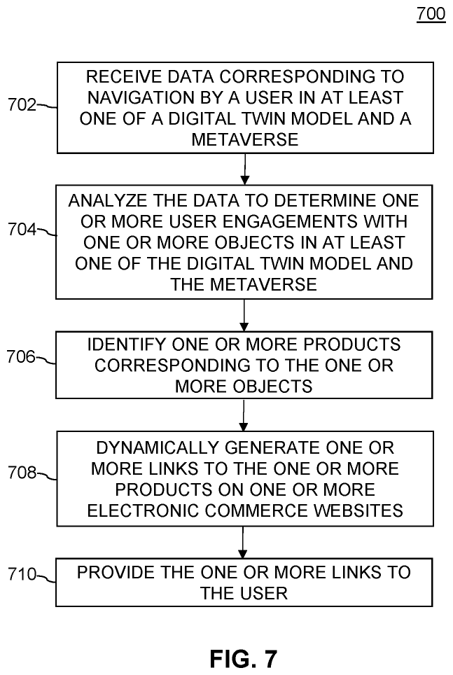

The operation of the information processing system 100 will now be described in further detail with reference to the flow diagram of FIG. 7. With reference to FIG. 7, a process 700 for analyzing and tracking user activity through a digital twin model(s) and/or the metaverse as shown includes steps 702 through 710, and is suitable for use in the system 100 but is more generally applicable to other types of processing systems configured for analyzing and tracking user activity through a digital twin model(s) and/or the metaverse.

In step 702, data corresponding to navigation by a user in at least one of a digital twin model and a metaverse is received. In step 704, the data is analyzed to determine one or more user engagements with one or more objects in at least one of the digital twin model and the metaverse. The analysis of the data can be performed using one or more machine learning models. The data corresponding to the navigation by a user comprises, for example, cookie data, user click history, user mouse activity and/or time spent on the one or more objects.

In step 706, one or more products corresponding to the one or more objects are identified. The identification of the one or more products can be performed using one or more machine learning models that, for example, interpret one or more images. The one or more machine learning models may be trained using historical image data. The identifying of the one or more products may comprise extracting and performing at least one of NLP and NLU of text from the one or more images.

In step 708, one or more links to the one or more products on one or more electronic commerce websites are dynamically generated. In step 710, the one or more links are provided to the user.

The dynamic generation of the one or more links may comprise determining the one or more electronic commerce websites including the one or more products, and identifying a price associated with the one or more products on respective ones of the one or more electronic commerce web sites. The respective ones of the one or more electronic commerce web sites may be ranked according to the price associated with the one or more products.

According to one or more embodiments, a signal is received from the one or more electronic commerce websites indicating that the user purchased the one or more products, and the purchase of the one or more products are flagged as one or more purchase conversions. A report corresponding to the one or more purchase conversions is generated.

In one or more embodiments, an image of the one or more user engagements with the one or more objects is captured, and an advertisement comprising an image of the one or more products and the one or more links is generated.

It is to be appreciated that the FIG. 7 process and other features and functionality described above can be adapted for use with other types of processing systems configured to analyze and track user activity through a digital twin model(s) and/or the metaverse.

The particular processing operations and other system functionality described in conjunction with the flow diagram of FIG. 7 are therefore presented by way of illustrative example only, and should not be construed as limiting the scope of the disclosure in any way. Alternative embodiments can use other types of processing operations. For example, the ordering of the process steps may be varied in other embodiments, or certain steps may be performed at least in part concurrently with one another rather than serially. Also, one or more of the process steps may be repeated periodically, or multiple instances of the process can be performed in parallel with one another.

Functionality such as that described in conjunction with the flow diagram of FIG. 7 can be implemented at least in part in the form of one or more software programs stored in memory and executed by a processor of a processing device such as a computer or server. As will be described below, a memory or other storage device having executable program code of one or more software programs embodied therein is an example of what is more generally referred to herein as a “processor-readable storage medium.”

The term “client,” “customer,” “administrator” or “user” herein is intended to be broadly construed so as to encompass numerous arrangements of human, hardware, software or firmware entities, as well as combinations of such entities. In some embodiments, the user devices 102 are assumed to be associated with system administrators, information technology (IT) managers, software developers or other authorized personnel configured to access and utilize the analysis platform 105.

Although shown as elements of the analysis platform 105, the visual AI module 110, data analytics module 120 and e-commerce AI module 130 in other embodiments can be implemented at least in part externally to the analysis platform 105, for example, as stand-alone servers, sets of servers or other types of systems coupled to a network.

It should be understood that the particular sets of modules and other components implemented in the system 100 as illustrated in FIG. 1 are presented by way of example only. In other embodiments, only subsets of these components, or additional or alternative sets of components, may be used, and such components may exhibit alternative functionality and configurations.

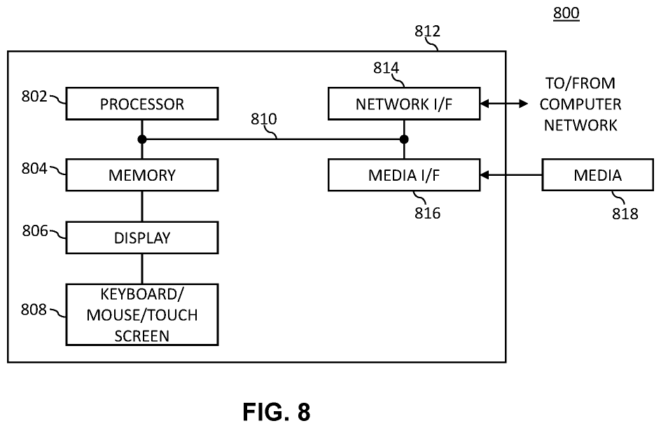

FIG. 8 illustrates a computer system 800 in accordance with which one or more embodiments of a user activity tracking and analysis system can be implemented. That is, one, more than one, or all of the components and/or functionalities shown and described in the context of FIGS. 1-7 can be implemented via the computer system depicted in FIG. 8.

By way of illustration, FIG. 8 depicts a processor 802, a memory 804, and an input/output (I/O) interface formed by a display 806 and a keyboard/mouse/touchscreen 808. More or less devices may be part of the I/O interface. The processor 802, memory 804 and I/O interface are interconnected via computer bus 810 as part of a processing unit or system 812 (such as a computer, workstation, server, client device, etc.). Interconnections via computer bus 810 are also provided to a network interface 814 and a media interface 816. Network interface 814 (which can include, for example, transceivers, modems, routers and Ethernet cards) enables the system to couple to other processing systems or devices (such as remote displays or other computing and storage devices) through intervening private or public computer networks (wired and/or wireless). Media interface 816 (which can include, for example, a removable disk drive) interfaces with media 818.

The processor 802 can include, for example, a central processing unit (CPU), a microprocessor, a microcontroller, an application-specific integrated circuit (ASIC), a field programmable gate array (FPGA) or other type of processing circuitry, as well as portions or combinations of such circuitry elements. Components of systems as disclosed herein can be implemented at least in part in the form of one or more software programs stored in memory and executed by a processor of a processing device such as processor 802. Memory 804 (or other storage device) having such program code embodied therein is an example of what is more generally referred to herein as a processor-readable storage medium. Articles of manufacture comprising such processor-readable storage media are considered embodiments. A given such article of manufacture may comprise, for example, a storage device such as a storage disk, a storage array or an integrated circuit containing memory. The term “article of manufacture” as used herein should be understood to exclude transitory, propagating signals.

Furthermore, memory 804 may comprise electronic memory such as random-access memory (RAM), read-only memory (ROM) or other types of memory, in any combination. The one or more software programs when executed by a processing device such as the processing unit or system 812 causes the device to perform functions associated with one or more of the components/steps of system/methodologies in FIGS. 1-7. One skilled in the art would be readily able to implement such software given the teachings provided herein. Other examples of processor-readable storage media embodying the embodiments may include, for example, optical or magnetic disks.

Still further, the I/O interface formed by devices 806 and 808 is used for inputting data to the processor 802 and for providing initial, intermediate and/or final results associated with the processor 802.

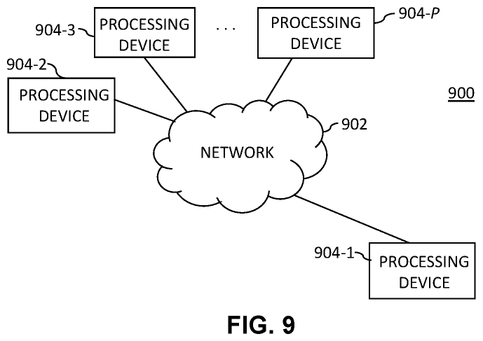

FIG. 9 illustrates a distributed communications/computing network (processing platform) in accordance with which one or more embodiments can be implemented. By way of illustration, FIG. 9 depicts a distributed communications/computing network (processing platform) 900 that includes a plurality of processing devices 904-1 through 904-P (herein collectively referred to as processing devices 904) configured to communicate with one another over a network 902.

The term “processing platform” as used herein is intended to be broadly construed so as to encompass, by way of illustration and without limitation, multiple sets of processing devices and one or more associated storage systems that are configured to communicate over one or more networks.

It is to be appreciated that one, more than one, or all of the processing devices 904 in FIG. may be configured as shown in FIG. 8. It is to be appreciated that the methodologies described herein may be executed in one such processing device 904, or executed in a distributed manner across two or more such processing devices 904. It is to be further appreciated that a server, a client device, a computing device or any other processing platform element may be viewed as an example of what is more generally referred to herein as a “processing device.” The network 902 may include, for example, a global computer network such as the Internet, a wide area network (WAN), a local area network (LAN), a satellite network, a telephone or cable network, or various portions or combinations of these and other types of networks (including wired and/or wireless networks).

As described herein, the processing devices 904 may represent a large variety of devices. For example, the processing devices 904 can include a portable device such as a mobile telephone, a smart phone, personal digital assistant (PDA), tablet, computer, a client device, etc. The processing devices 904 may alternatively include a desktop or laptop personal computer (PC), a server, a microcomputer, a workstation, a kiosk, a mainframe computer, or any other information processing device which can implement any or all of the techniques detailed in accordance with one or more embodiments.

One or more of the processing devices 904 may also be considered a “user.” The term “user,” as used in this context, should be understood to encompass, by way of example and without limitation, a user device, a person utilizing or otherwise associated with the device, or a combination of both. An operation described herein as being performed by a user may therefore, for example, be performed by a user device, a person utilizing or otherwise associated with the device, or by a combination of both the person and the device, the context of which is apparent from the description.

Additionally, as noted herein, one or more modules, elements or components described in connection with the embodiments can be located geographically-remote from one or more other modules, elements or components. That is, for example, the modules, elements or components shown and described in the context of FIGS. 1-7 can be distributed in an Internet-based environment, a mobile telephony-based environment, a kiosk-based environment and/or a local area network environment. The transaction analysis system, as described herein, is not limited to any particular one of these implementation environments. However, depending on the operations being performed by the system, one implementation environment may have some functional and/or physical benefits over another implementation environment.

The processing platform 900 shown in FIG. 9 may comprise additional known components such as batch processing systems, parallel processing systems, physical machines, virtual machines, virtual switches, storage volumes, etc. Again, the particular processing platform shown in this figure is presented by way of example only, and may include additional or alternative processing platforms, as well as numerous distinct processing platforms in any combination. Also, numerous other arrangements of servers, clients, computers, storage devices or other components are possible in processing platform 900.

Furthermore, it is to be appreciated that the processing platform 900 of FIG. 9 can comprise virtual machines (VMs) implemented using a hypervisor. A hypervisor is an example of what is more generally referred to herein as “virtualization infrastructure.” The hypervisor runs on physical infrastructure. As such, the techniques illustratively described herein can be provided in accordance with one or more cloud services. The cloud services thus run on respective ones of the virtual machines under the control of the hypervisor. Processing platform 900 may also include multiple hypervisors, each running on its own physical infrastructure. Portions of that physical infrastructure might be virtualized.

As is known, virtual machines are logical processing elements that may be instantiated on one or more physical processing elements (e.g., servers, computers, processing devices). That is, a “virtual machine” generally refers to a software implementation of a machine (i.e., a computer) that executes programs like a physical machine. Thus, different virtual machines can run different operating systems and multiple applications on the same physical computer. Virtualization is implemented by the hypervisor which is directly inserted on top of the computer hardware in order to allocate hardware resources of the physical computer dynamically and transparently. The hypervisor affords the ability for multiple operating systems to run concurrently on a single physical computer and share hardware resources with each other.

It is to be appreciated that combinations of the different implementation environments are contemplated as being within the scope of the embodiments. One of ordinary skill in the art will realize alternative implementations given the illustrative teachings provided herein.

The terminology used herein is for the purpose of describing particular embodiments only and is not intended to be limiting. As used herein, the singular forms “a,” “an” and “the” are intended to include the plural forms as well, unless the context clearly indicates otherwise. Additionally, the terms “comprises” and/or “comprising,” as used herein, specify the presence of stated values, features, steps, operations, modules, elements, and/or components, but do not preclude the presence or addition of another value, feature, step, operation, module, element, component, and/or group thereof.

Advantageously, the embodiments use machine learning techniques to analyze user navigation through a digital twin model(s) and/or in the metaverse, and to identify user interactions with objects in the digital twin model(s) and/or the metaverse. The embodiments also identify products corresponding to the objects with which the user engages, and based on the identified products, generates links to e-commerce websites where the user may purchase the products. Conventional techniques fail to provide such analysis of user activity in a digital twin model(s) and/or the metaverse, and do not provide the capability to dynamically generate e-commerce links to products corresponding to the objects in the digital twin model(s) and/or the metaverse with which the user engages. As an additional advantage, the embodiments generate reports of purchases of the products identified in generated links.

Additionally, unlike conventional approaches, the embodiments generate advertisements based on user engagements with objects in the digital twin model(s) and/or in the metaverse, and provide techniques for storing the user activity and corresponding analysis as blockchain entries.

Although illustrative embodiments have been described herein with reference to the accompanying drawings, it is to be understood that the embodiments are not limited to those precise descriptions, and that various other changes and modifications may be made by one skilled in the art without departing from the scope or spirit of the disclosure. Numerous other alternative embodiments within the scope of the appended claims will be readily apparent to those skilled in the art.

What is claimed is:

1. An apparatus comprising:
at least one processing platform comprising a plurality of processing devices;
said at least one processing platform being configured:
to receive data corresponding to navigation by a user in at least one of a digital twin model and a metaverse;
to analyze the data to determine one or more user engagements with one or more objects in at least one of the digital twin model and the metaverse;
to identify one or more products corresponding to the one or more objects;
to dynamically generate one or more links to the one or more products on one or more electronic commerce websites; and
to provide the one or more links to the user.

2. The apparatus of claim 1 wherein the analysis of the data is performed using one or more machine learning models.

3. The apparatus of claim 1 wherein the identification of the one or more products is performed using one or more machine learning models.

4. The apparatus of claim 3 wherein the one or more machine learning models interpret one or more images.

5. The apparatus of claim 4 wherein said at least one processing platform is further configured to train the one or more machine learning models using historical image data.

6. The apparatus of claim 4 wherein, in identifying the one or more products, said at least one processing platform is configured to extract and perform at least one of natural language understanding and natural language processing of text from the one or more images.

7. The apparatus of claim 1 wherein the data corresponding to the navigation by a user comprises at least one of cookie data, user click history, user mouse activity and time spent on the one or more objects.

8. The apparatus of claim 1 wherein, in dynamically generating the one or more links, said at least one processing platform is configured:
to determine the one or more electronic commerce websites including the one or more products; and
to identify a price associated with the one or more products on respective ones of the one or more electronic commerce websites.

9. The apparatus of claim 8 wherein, in dynamically generating the one or more links, said at least one processing platform is further configured to rank the respective ones of the one or more electronic commerce websites according to the price associated with the one or more products.

10. The apparatus of claim 1 wherein said at least one processing platform is further configured:
to receive a signal from the one or more electronic commerce websites indicating that the user purchased the one or more products; and
to flag the purchase of the one or more products as one or more purchase conversions.

11. The apparatus of claim 10 wherein said at least one processing platform is further configured to generate a report corresponding to the one or more purchase conversions.

12. The apparatus of claim 1 wherein said at least one processing platform is further configured to capture an image of the one or more user engagements with the one or more objects.

13. The apparatus of claim 1 wherein said at least one processing platform is further configured to generate an advertisement comprising an image of the one or more products and the one or more links.

14. A method comprising:
receiving data corresponding to navigation by a user in at least one of a digital twin model and a metaverse;
analyzing the data to determine one or more user engagements with one or more objects in at least one of the digital twin model and the metaverse;
identifying one or more products corresponding to the one or more objects;
dynamically generating one or more links to the one or more products on one or more electronic commerce websites; and
providing the one or more links to the user;
wherein the method is performed by at least one processing platform comprising at least one processing device comprising a processor coupled to a memory.

15. The method of claim 14 wherein the data corresponding to the navigation by a user comprises at least one of cookie data, user click history, user mouse activity and time spent on the one or more objects.

16. The method of claim 14 further comprising:
receiving a signal from the one or more electronic commerce websites indicating that the user purchased the one or more products; and
flagging the purchase of the one or more products as one or more purchase conversions.

17. The method of claim 14 further comprising capturing an image of the one or more user engagements with the one or more objects.

18. A computer program product comprising a non-transitory processor-readable storage medium having stored therein program code of one or more software programs, wherein the program code when executed by at least one processing platform causes said at least one processing platform:
to receive data corresponding to navigation by a user in at least one of a digital twin model and a metaverse;
to analyze the data to determine one or more user engagements with one or more objects in at least one of the digital twin model and the metaverse;
to identify one or more products corresponding to the one or more objects;
to dynamically generate one or more links to the one or more products on one or more electronic commerce websites; and
to provide the one or more links to the user.

19. The computer program product of claim 18 wherein the program code further causes said at least one processing platform:
to receive a signal from the one or more electronic commerce websites indicating that the user purchased the one or more products; and
to flag the purchase of the one or more products as one or more purchase conversions.

20. The computer program product of claim 18 wherein the program code further causes said at least one processing platform to capture an image of the one or more user engagements with the one or more objects.
